(19) United States
(12) Patent Application Publication
(10) Pub. No.: US 2014/0000810 A1
(43) Pub. Date: Jan. 2, 2014

(54) Plasma Activation System

(71) Applicants: Mark A. Franklin, Scottsdale, AZ (US); William J. Franklin, Phoenix, AZ (US)

(72) Inventors: Mark A. Franklin, Scottsdale, AZ (US); William J. Franklin, Phoenix, AZ (US)

(21) Appl. No.: 13/720,517

(22) Filed: Dec. 19, 2012

Related U.S. Application Data
(60) Provisional application No. 61/581,575, filed on Dec. 29, 2011.
(60) Provisional application No. 61/649,195, filed on May 18, 2012.

(51) Int. Cl. H01L 21/67

(52) U.S. Cl. CPC H01L 21/67069
USPC 156/345.48; 156/345.51; 156/345.54

(57) ABSTRACT

Improved systems relating to modifying the surface properties of at least one material using plasma-based processes. Application of methods and apparatus of the system are particularly useful in semiconductor processing.

### CROSS-REFERENCE TO RELATED APPLICATION

The present application is related to and Claims priority from prior provisional application Ser. No. 61/649,195, filed May 18, 2012, entitled “PLASMA ACTIVATION SYSTEMS”; and, this application is related to and Claims priority from prior provisional application Ser. No. 61/581,575, filed Dec. 29, /2011, entitled “PLASMA ACTIVATION SYSTEMS”, the contents of all of which are incorporated herein by this reference and are not admitted to be prior art with respect to the present invention by the mention in this cross-reference section.

### BACKGROUND

This invention relates to providing improved plasma activation systems. More particularly, this invention relates to providing an improved system for modifying the surface properties of a material using plasma-based processes.

Modifying the surface properties of a semiconductor substrate is a necessary step in many semiconductor fabrication processes. This may include physical and/or chemical modification of the first few molecular layers of a surface, while maintaining the inherent properties within the remainder of the substrate. Improving the performance, efficiency, and cost of such processes would be of benefit to many in the field.

### OBJECTS AND FEATURES OF THE INVENTION

A primary object and feature of the present invention is to provide a system to address the above-mentioned need. It is a further object and feature of the present invention to provide such a system for modifying the surface properties of a semiconductor substrate using one or more plasma-based processes. It is another object and feature of the present invention to provide such a system utilizing a source that allows a broader process window without a decrease in performance.

It is a further object and feature of the present invention to provide such a system having a source allowing for multi-semiconductor-wafer operation. It is another object and feature of the present invention to provide such a system utilizing a source that requires essentially no setup/production time to change between semiconductor-wafer sizes. It is a further object and feature of the present invention to provide such a system having a source that significantly limits damage to device wafers under standard operating conditions.

Another object and feature of the present invention is to provide such a system comprising apparatus that may be adjusted to provide both surface activation of a substrate, without etching, and surface etching of a substrate.

A further primary object and feature of the present invention is to provide such a system that is efficient, inexpensive, and useful. Other objects and features of this invention will become apparent with reference to the following descriptions.

### SUMMARY OF THE INVENTION

In accordance with a preferred embodiment hereof, this invention provides a system, relating to controlling a plasma to activate a surface of at least one substrate with minimal etching, comprising: at least one container structured and arranged to contain the at least one substrate and the plasma; at least one plasma creator structured and arranged to create the plasma; at least one positioner structured and arranged to position the surface within the plasma; and at least one envelope generator structured and arranged to generate at least one envelope around the at least one substrate and at least partially the plasma;

wherein the plasma comprises at least one surface-etching constituent and at least one activating constituent; wherein such at least one envelope is structured and arranged to control plasma composition to minimize content of such at least one surface-etching constituent of the plasma and maximize content of such at least one activating constituent of the plasma adjacent the surface; and wherein the plasma is controlled to activate the surface of the at least one substrate with minimal etching.

Moreover, it provides such a system wherein such at least one envelope generator comprises at least one geometry controller structured and arranged to control geometry of such at least one envelope. Additionally, it provides such a system wherein such at least one envelope generator is structured and arranged to generate such at least one envelope structured and arranged to control plasma composition to minimize content of charged particles and maximize content of uncharged radicals adjacent the surface. Also, it provides such a system wherein such at least one positioner comprises at least one adjuster structured and arranged to adjust position of the surface within the plasma.

In addition, it provides such a system further comprising at least two electrodes structured and arranged to interact with at least one electromagnetic signal. And, it provides such a system wherein at least one of such at least two electrodes is at ground potential. Further, it provides such a system wherein at least one of such at least two electrodes is structured and arranged to transmit at least one radio frequency signal. Even further, it provides such a system wherein such at least one plasma creator and such at least one enveloper each comprise such at least one radio frequency signal. Moreover, it provides such a system wherein both such at least one radio frequency signal of such at least one plasma creator and such at least one radio frequency signal of such at least one enveloper transmit from a common electrode of such at least two electrodes.

In accordance with another preferred embodiment hereof, this invention provides a system, relating to altering control of a plasma between activating a surface of at least one substrate with minimal etching and etching the surface of the at least one substrate, comprising: at least one container structured and arranged to contain the at least one substrate and the plasma; at least two electrodes structured and arranged to interact with at least one electromagnetic signal; at least one plasma creator structured and arranged to create the plasma; wherein the plasma comprises at least one surface-etching constituent and at least one activating constituent; at least one positioner structured and arranged to position the surface within the plasma; wherein such at least one positioner comprises one of such at least two electrodes; wherein such at least one positioner comprises at least one adjuster structured and arranged to adjust distance between such at least two electrodes; at least one envelope generator structured and arranged to generate at least one envelope inside such at least one container; wherein such at least one adjuster comprises at least one etching-distance setting and at least one activation-distance setting; wherein such at least one envelope generator comprises at least one etching-envelope setting and at least one activation-envelope setting; wherein, when such at least one adjuster is set to such at least one activation-distance setting and when such at least one envelope generator is set to such at least one activation-envelope setting, such at least one envelope generator is structured and arranged to generate such at least one envelope structured and arranged to control plasma composition to minimize content of such at least one surface-etching constituent of the plasma and maximize content of such at least one activating constituent of the plasma adjacent the surface, and the plasma is controlled to activate the surface of the at least one substrate with minimal etching; and wherein, when such at least one adjuster is set to such at least one etching-distance setting and when such at least one envelope generator is set to such at least one etching-envelope setting, such at least one envelope generator is structured and arranged to generate such at least one envelope structured and arranged to permit such at least one surface-etching constituent of the plasma adjacent the surface, and the plasma is allowed to etch the surface of the at least one substrate.

Additionally, it provides such a system wherein at least one of such at least two electrodes is at ground potential. Also, it provides such a system wherein at least one of such at least two electrodes is structured and arranged to transmit at least one radio frequency signal. In addition, it provides such a system wherein such at least one plasma creator and such at least one envelope generator each comprise such at least one radio frequency signal. And, it provides such a system wherein both such at least one radio frequency signal of such at least one plasma creator and such at least one radio frequency signal of such at least one envelope generator transmit from a common electrode of such at least two electrodes. Further, it provides such a system wherein such at least one etching-envelope setting comprises at least one integral multiple frequency, wherein frequency of such at least one radio frequency signal of such at least one plasma creator is an integral multiple of frequency of such at least one radio frequency signal of such at least one envelope generator. Even further, it provides such a system wherein such at least one activation-envelope setting comprises at least one non-integral multiple frequency, wherein frequency of such at least one radio frequency signal of such at least one plasma creator is a non-integral multiple of frequency of such at least one radio frequency signal of such at least one envelope generator.

In accordance with another preferred embodiment hereof, this invention provides a system, relating to controlling a plasma to activate a surface of at least one substrate with minimal etching, comprising: container means for containing the at least one substrate and the plasma; plasma creator means for creating the plasma; wherein the plasma comprises at least one surface-etching constituent and at least one activating constituent positioner means for positioning the surface within the plasma; enveloper means for enveloping the at least one substrate and at least partially the plasma in at least one envelope; wherein such enveloper means comprises controller means for controlling plasma composition to minimize content of such at least one surface-etching constituent of the plasma and maximize content of such at least one activating constituent of the plasma adjacent the surface; and wherein the plasma is controlled to activate the surface of the at least one substrate with minimal etching.

Even further, it provides such a system wherein enveloper means comprises geometry controller means for controlling geometry of such at least one envelope. Even further, it provides such a system wherein such enveloper means comprises such controller means for controlling plasma composition to minimize content of charged particles and maximize content of uncharged radicals adjacent the surface. Even further, it provides such a system wherein such positioner means comprises adjuster means for adjusting position of the surface.

In accordance with other preferred embodiments hereof, this invention provides each and every novel feature, element, combination, step and/or method disclosed or suggested by this patent application.

### Definitions and Supporting Data

Plasma: In physics and chemistry, plasma is a state of matter similar to gas. However, unlike a gas, plasma is electromagnetically active. The electromagnetic properties stem from ionization within the plasma. Plasmas are therefore electrically conductive and susceptible to influence from electromagnetic fields. Further, ionization occurs in such a way as to leave the whole charge neutral like a gas of similar atomic composition. The energetic state of plasma also increases incidences of free-radicals of both charged and uncharged states.

Degree of ionization: In order for plasma to exist, ionization is required. The degree of ionization of a plasma is a measure of the amount of particles in an ionized state (ions or anions). Ordinarily the degree of ionization is altered through the temperature of the plasma.

Diatomic Molecules: Diatomic molecules are molecules of only two atoms, whether of the same or different chemical elements. The prefix di-comes from Greek where it means two. Common diatomic molecules are hydrogen (H2), nitrogen (N2), oxygen (O2), and carbon monoxide (CO).

Polyatomic Molecules: Polyatomic Molecules are molecules composed of two or more atoms. While any diatomic molecule is considered also polyatomic, additional molecules, such as water (H2O), carbon dioxide (CO2), etc. are also polyatomic.

Radicals: Radicals (often referred to as free radicals) are atoms, molecules, or ions with unpaired valence electrons (or outer electrons) with an open shell configuration. Radicals may be positive, negative in charge or carry no charge at all. With some exceptions, the unpaired valence electrons cause radicals to be highly chemically reactive, capable of bonding strongly with other particles.

Plasma Activation bond Theory: A plasma activation bond may eliminate or reduce residual moisture at the interface, provide chemical species needed for interface reaction and eliminate un-necessary intermediates, catalyze reaction kinetics with near surface electric field via radicals with no residual plasma damage, reduce or eliminate contamination and particles with a controlled environment.

### BRIEF DESCRIPTION OF THE DRAWINGS

FIG. 1 shows a schematic diagram, illustrating a plasma-based surface activation process and apparatus arrangements, according to preferred embodiments of the present invention.

FIG. 2 shows a diagrammatic view, illustrating plasma particle biasing, according to the preferred embodiment of FIG. 1.

FIG. 3 shows a diagrammatic view, illustrating an alternate etching configuration, according to the preferred embodiment of FIG.1.

### DETAILED DESCRIPTION OF THE BEST MODES AND PREFERRED EMBODIMENTS OF THE INVENTION

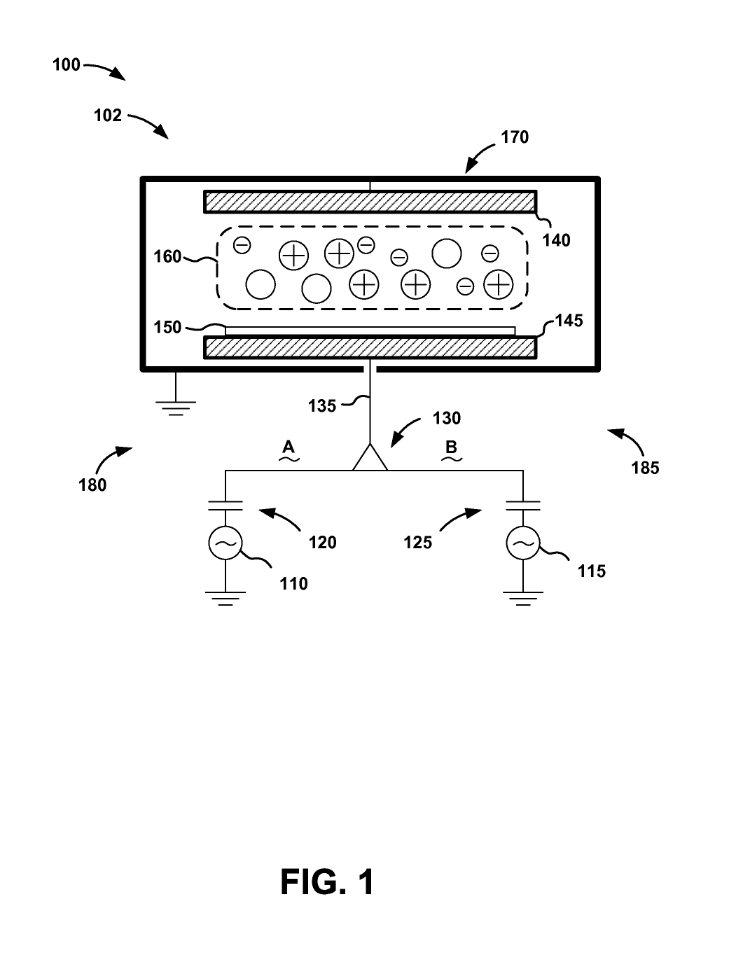

FIG. 1 shows a schematic diagram illustrating a plasma-based surface activation system 100 and plasma-based surface activation apparatus 102 according to preferred embodiments of the present invention. Plasma-based surface activation apparatus 102 preferably comprises a first radio frequency (RF) generator 110, a second RF generator 115, a signal combiner 130, an upper electrode 140, a lower isolated electrode 145, and an enclosable processing chamber 170, as shown.

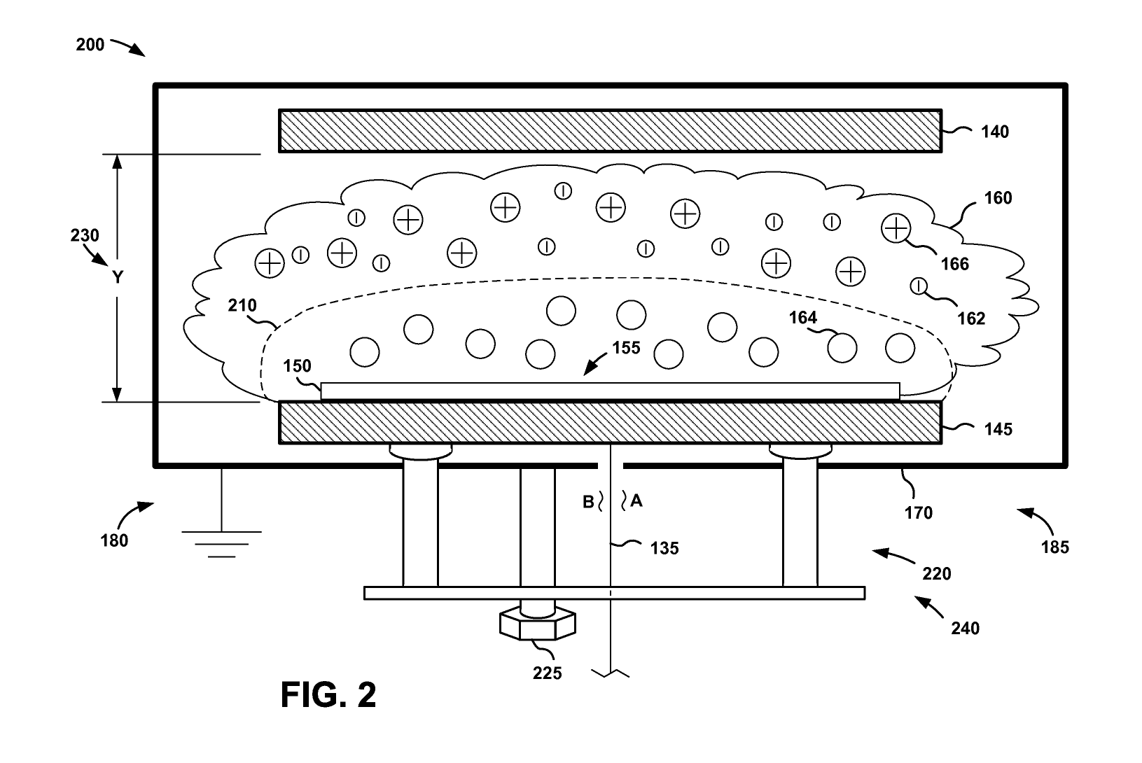

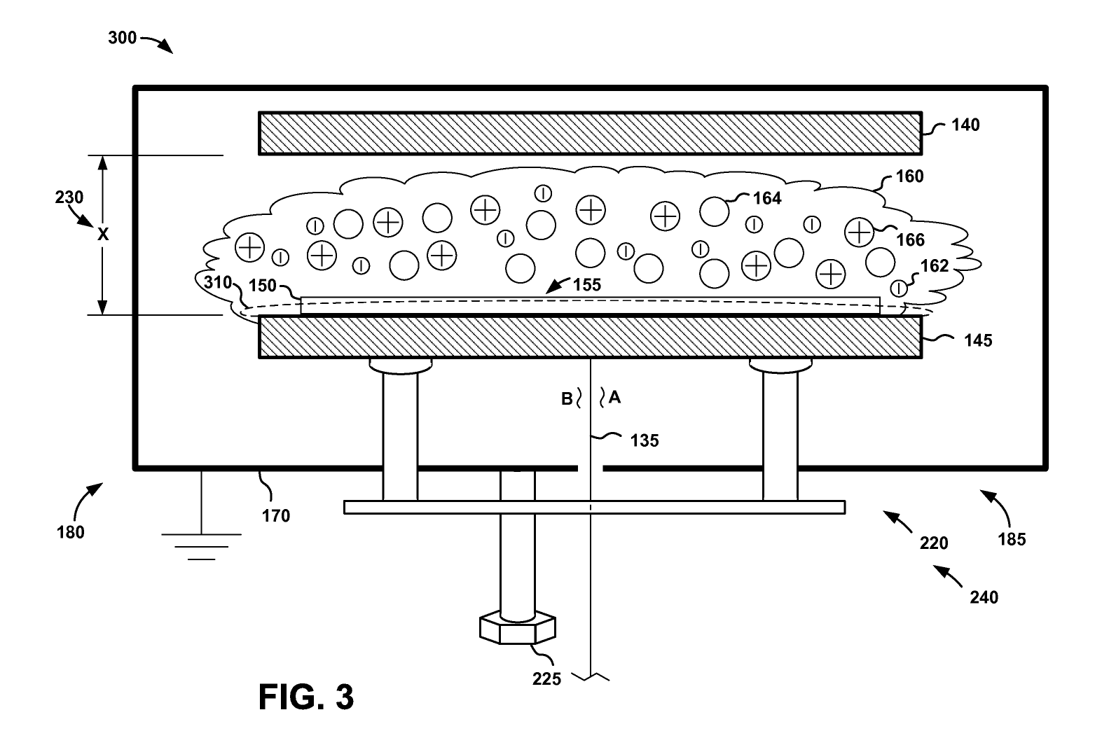

The lower isolated electrode 145 is preferably coupled to RF generator 110 and second RF generator 115, as shown, and is preferably configured to receive RF energy [RF signal (A) and RF signal (B) respectively] from both generators through transmission line 135. Signal combiner 130 preferably comprises a high pass filter portion 120 and a low pass filter portion 125, as shown. Upper electrode 140 is preferably at ground potential. Lower isolated electrode 145 is preferably designed to permit adjustable spacing (see FIG. 2 and FIG. 3).

Enclosable processing chamber 170 preferably encloses upper electrode 140, lower isolated electrode 145 and at least one substrate 150, preferably at least one wafer. Enclosable processing chamber 170 preferably contains plasma 160 during processing. Enclosable processing chamber 170 (at least embodying herein at least one container structured and arranged to contain the at least one substrate and the plasma; and at least embodying herein container means for containing the at least one substrate and the plasma) preferably is grounded, preferably to both control the plasma reaction inside and preferably to negate external electromagnetic fields (Faraday shielding).

Upper electrode 140 and lower isolated electrode 145 preferably comprise spacing 230 of greater than about four centimeters (cm) apart [activation separation (Y)], as shown in FIG. 2, in use during surface activation process 100. Upon reading the teachings of this specification, those skilled in the art will now appreciate that, under appropriate circumstances, considering such issues as cost, future technologies, etc., other electrode spacing(s), such as, for example, greater than eight cm, greater than ten cm, etc., may suffice.

At least one plasma generator 180 preferably comprises first RF generator 110 and lower isolated electrode 145. First RF generator 110 preferably generates RF signal (A) at a frequency to create plasma 160 from at least one polyatomic substance present in enclosable processing chamber 170 in use. First RF generator 110 preferably is electrically coupled to lower isolated electrode 145, preferably to transmit RF signal (A) inside processing chamber 170, as shown. Upon reading the teachings of this specification, those skilled in the art will now appreciate that, under appropriate circumstances, considering such issues as cost, future technologies, etc., other plasma generators, such as, for example, laser ablation plasma generators, microwave frequency generators, multiple direction electrodes etc., may suffice.

Such at least one polyatomic substance preferably comprises oxygen, preferably introduced oxygen and residual surface water. When such at least one polyatomic substance is subjected to RF signal (A), such at least one polyatomic substance absorbs energy from RF signal (A) creating plasma 160. This arrangement at least embodies herein at least one plasma creator structured and arranged to create the plasma; and this arrangement at least embodies herein plasma creator means for creating the plasma. Upon reading the teachings of this specification, those skilled in the art will now appreciate that, under appropriate circumstances, considering such issues as future fabrication methods, materials, costs, etc., other plasma-producing substances, such as, for example, hydrogen, nitrogen, carbon dioxide, carbon monoxide, other diatomic molecules, other polyatomic molecules, etc., may suffice.

Particle control generator 185 (at least embodying herein at least one envelope generator structured and arranged to generate at least one envelope around the at least one substrate and at least partially the plasma) preferably comprises second RF generator 115 and lower isolated electrode 145. Second RF generator 115 preferably generates RF signal (B) at a frequency to induce an ion-rejecting sheath 210 around lower isolated electrode 145 and at least one substrate 150, in use (at least embodying herein at least one enveloper structured and arranged to envelope the at least one substrate and at least partially the plasma in at least one envelope; and at least embodying herein enveloper means for enveloping the at least one substrate and at least partially the plasma in at least one envelope). Second RF generator 115 preferably is also electrically coupled to lower isolated electrode 145, preferably to transmit RF signal (B) inside processing chamber 170, as shown. Ion-rejecting sheath 210 preferably acts as a filter, preferably allowing uncharged radicals 164 to reach surface 155 of substrate 150 and rejecting energetic ions and anions from within ion-rejecting sheath 210, as shown in FIG. 2; thus, control of the composition of the plasma interacting with surface 155 is preferably provided (this arrangement at least herein embodying wherein such at least one envelope is structured and arranged to control plasma composition to minimize content of such at least one surface-etching constituent of the plasma and maximize content of such at least one activating constituent of the plasma adjacent the surface; and, this arrangement at least herein embodying wherein such at least one enveloper comprises at least one controller structured and arranged to control plasma composition to minimize content of such at least one surface-etching constituent of the plasma and maximize content of such at least one activating constituent of the plasma adjacent the surface; and this arrangement at least herein embodying wherein such enveloper means comprises controller means for controlling plasma composition to minimize content of such at least one surface-etching constituent of the plasma and maximize content of such at least one activating constituent of the plasma adjacent the surface; and at least herein embodying wherein such at least one controller controls plasma composition to minimize content of charged particles and maximize content of uncharged radicals adjacent the surface; and, at least herein embodying wherein such enveloper means comprises such controller means for controlling plasma composition to minimize content of charged particles and maximize content of uncharged radicals adjacent the surface).

In accordance with the present system, the frequencies of the signals produced by first RF generator 110 and second RF generator 115 preferably are non-integral multiples of each other. This ensures that there is no interaction between RF signal (A) and RF signal (B), such as resonance. In one preferred example arrangement of the system, RF generator 110 preferably operates at about 399 kilohertz (kHz) and RF generator 115 preferably operates at about 50 kHz. Upon reading the teachings of this specification, those skilled in the art will now appreciate that, under appropriate circumstances, considering such issues as cost, future technologies, etc., other frequencies, such as, for example, higher non-integral multiple frequencies, lower non-integral multiple frequencies, greater-difference non-integral multiple frequencies, lesser-difference non-integral multiple frequencies, etc., may suffice.

FIG. 2 shows a diagrammatic view, illustrating plasma particle biasing, according to the preferred embodiment of FIG. 1.

Substrate 150, to be surface treated, preferably rests upon lower isolated electrode 145, as shown, preferably in a position between lower isolated electrode 145 and upper electrode 140. Such placement positions substrate 150 within plasma 160 during processing. This arrangement at least embodies herein at least one positioner structured and arranged to position the surface within the plasma. Upon reading the teachings of this specification, those skilled in the art will now appreciate that, under appropriate circumstances, considering such issues as cost, future technologies, etc., other substrate placement systems, such as, for example, independent stages, stacked stages, free-floating suspension, etc., may suffice.

Plasma 160 preferably comprises ions 162 (at least herein embodying wherein the plasma comprises at least one surface-etching constituent), anions 166 and uncharged radicals 164 (at least herein embodying wherein the plasma comprises at least one activating constituent). It is noted that RF signal (A), as shown in FIG. 1, is preferably a low-frequency signal. This produces plasma 160 having low ion density but producing significant amounts of radicals. When created from oxygen and water, superoxide anions, peroxide, hydroxyl radicals, and hydroxyl ions are formed in plasma 160.

Preferably, by providing the addition of lower RF signal (B) on lower isolated electrode 145, the non-ion radicals 164 created by RF signal (A) are allowed to pass through ion-rejecting sheath 210 to the substrate surface without ion-etching effects on surface 155, preferably due to ion rejection formed from the frequencies of RF signal (A) and RF signal (B) being at non-integral multiples of each other. Thus, the surface preferably is “activated” by the presence of these non-charged radicals 164, while preferably protected against etching.

The above-described apparatus arrangements at least embody herein at least one envelope generator structured and arranged to generate at least one envelope inside such at least one container.

As a result, a plasma exposure of a substrate surface made in accordance with the present preferred system preferably leaves non-charged radicals 164 on surface 155. Non-charged radicals 164 have a very high free energy. Consequently, non-charged radicals 164 are very willing to bond with other elements in substrate 150 to lower its free energy state. Thus, when two such treated surfaces are brought together, a chemical bonding preferably occurs resulting in a large free energy drop and development of a strong bond. A similar result is observed even if only one of the substrate surfaces is treated. The high free energy is also the source of the accelerated kinetic behavior of the bond strength development during post activation thermal treatments. The free energy preferably provides the driving force for the transition from Van der Waals bonding to covalent or ionic bonds.

Applicant has found through testing that a substrate surface treated by plasma activation according to the present system bonds exceptionally well to the surface of a second substrate. By treating both substrate surfaces to be bonded, an exceptionally strong bond can be achieved. Moreover, the treated surface(s) is substantially free of physical ion bombardment effects.

In use, processing of substrate 150 preferably proceeds by: placing substrate 150 in enclosable processing chamber 170 on lower isolated electrode 145; sealing enclosable processing chamber 170; evacuating ambient air inside enclosable processing chamber 170; introducing a plasma forming gas, preferably oxygen; generating plasma 160 and ion-rejecting sheath 210 inside enclosable processing chamber 170; shutting down generation of plasma 160 and ion-rejecting sheath 210; unsealing enclosable processing chamber 170; wherein surface 155 of substrate 150 is now activated and may be bonded to another receptive substrate.

FIG. 3 shows a diagrammatic view, illustrating an alternate etching configuration, according to the preferred embodiment of FIG.1.

Another advantage of the present design is that spacing 230 of the electrodes (greater than about four cm) does not affect the quality of the surface activation and preferably will allow a multiple number of wafers (substrate 150) at a time (i.e., three 6-inch wafer on a 12-inch electrode). Particle control generator 185 preferably comprises at least one sheath geometry controller 240 (at least herein embodying wherein enveloper means comprises geometry controller means for controlling geometry of such at least one envelope) and at least one particle interaction controller. In the preferred design arrangements of FIG. 2 and FIG. 3, sheath geometry controller 240 preferably comprises lower isolated electrode 145 comprising at least one adjustable stage 220 to permit adjustable spacing of the electrodes.

Adjustable stage 220 (at least herein embodying wherein such at least one positioner comprises at least one adjuster structured and arranged to adjust position of the surface; and at least herein embodying wherein such positioner means comprises adjuster means for adjusting position of the surface) preferably allows a lower movable chuck 225 to adjustably set spacing 230 between the two electrodes.

Such at least one particle interaction controller preferably comprises adjustable frequency control of RF signal (A) and RF signal (B). Adjustment of either or both RF signal (A) and RF signal (B) to be at resonant frequencies preferably adjusts strength of ion-rejection of ion-rejecting sheath 210, preferably between complete rejection and complete passing of charged particles. With such adjustment, generation of ion-rejecting sheath 210 (representative of greater rejection of charge particles) becomes generation of sheath 310 (representative of greater charged particle passing).

This preferred feature provides the end user the ability to configure the present system to a “surface-etch” mode 300, if desired, as shown in FIG. 3. This adjustment feature is potentially of great value to smaller facilities seeking to maximize the value of a single processing apparatus. Upon reading the teachings of this specification, those skilled in the art will now appreciate that, under appropriate circumstances, considering such issues as cost, future technologies, etc., other adjustable stages, such as, for example, transmission carrying stages, transmission line pass-through adjustable chucks, etc., may suffice.

The conversion steps to modify the unit for etching preferably include:
1) adjusting spacing 230 of the electrodes from activation separation (Y) to within about four centimeters proximity [etching separation (X)] (at least herein embodying wherein such at least one adjuster comprises at least one etching-distance setting and at least one activation-distance setting), and
2) adjusting the frequency of RF signal (A) from a non-integral multiple to an integral multiple of the frequency of RF signal (B), as generally shown in FIG. 1 (at least herein embodying wherein such at least one envelope generator comprises at least one etching-envelope setting and at least one activation-envelope setting).

In the above preferred alternate configuration, the system will etch surface 155. By changing spacing 230 and adjusting frequencies to create resonance (at integral multiples), the influence of sheath 310 on ion rejection is minimized. Sheath 310 is in effect preferably adjusted in geometry and properties, as compared with ion-rejecting sheath 210, preferably allowing for ion bombardment and etching of surface 155 (this arrangement at least herein embodying wherein such at least one enveloper comprises at least one geometry controller structured and arranged to control geometry of such at least one envelope; and at least herein embodying wherein such enveloper means comprises geometry control means for controlling geometry of such at least one envelope). Therefore, the systems disclosed herein preferably comprise a dual function apparatus, preferably allowing for efficient use of space and equipment in use.

In use for etching, processing of substrate 150 preferably proceeds by: placing substrate 150 in enclosable processing chamber 170 on lower isolated electrode 145 (spacing 230 adjusted for etching mode); sealing enclosable processing chamber 170; evacuating ambient air inside enclosable processing chamber 170; introducing a plasma forming gas, preferably oxygen; generating plasma 160 and sheath 310 inside enclosable processing chamber 170 (where the RF generators have been accordingly adjusted in frequency for etching); shutting down generation of plasma 160 and ion-rejecting sheath 210; unsealing enclosable processing chamber 170; wherein surface 155 of substrate 150 is now etched and may be utilized accordingly.

In summary, the present system source preferably at least provides:
1) A broader process window without decreased performance
2) Multi-wafer operation
3) Essentially no time requirement to change wafer sizes during production
4) Essentially no damage to device wafers under standard operating conditions
5) The ability to provide multiple operational modes

Although applicant has described applicant's preferred embodiments of this invention, it will be understood that the broadest scope of this invention includes modifications such as diverse shapes, sizes, and materials. Such scope is limited only by the below Claims as read in connection with the above specification. Further, many other advantages of applicant's invention will be apparent to those skilled in the art from the above descriptions and the below Claims.

What is claimed is:

1) A system, relating to controlling a plasma to activate a surface of at least one substrate with minimal etching, comprising:
a) at least one container structured and arranged to contain the at least one substrate and the plasma;
b) at least one plasma creator structured and arranged to create the plasma;
c) at least one positioner structured and arranged to position the surface within the plasma; and
d) at least one envelope generator structured and arranged to generate at least one envelope around the at least one substrate and at least partially the plasma;
e) wherein the plasma comprises at least one surface-etching constituent and at least one activating constituent;
f) wherein such at least one envelope is structured and arranged to control plasma composition to minimize content of such at least one surface-etching constituent of the plasma and maximize content of such at least one activating constituent of the plasma adjacent the surface; and
g) wherein the plasma is controlled to activate the surface of the at least one substrate with minimal etching.

2) The system, according to claim 1, wherein said at least one envelope generator comprises at least one geometry controller structured and arranged to control geometry of such at least one envelope.

3) system, according to claim 1, wherein said at least one envelope generator is structured and arranged to generate such at least one envelope structured and arranged to control plasma composition to minimize content of charged particles and maximize content of uncharged radicals adjacent the surface.

4) system, according to claim 1, wherein said at least one positioner comprises at least one adjuster structured and arranged to adjust position of the surface within the plasma.

5) system, according to claim 1, further comprising at least two electrodes structured and arranged to interact with at least one electromagnetic signal.

6) The system, according to claim 5, wherein at least one of said at least two electrodes is at ground potential.

7) The system, according to claim 6, wherein at least one of said at least two electrodes is structured and arranged to transmit at least one radio frequency signal.

8) The system, according to claim 7, wherein said at least one plasma creator and said at least one enveloper each comprise such at least one radio frequency signal.

9) The system, according to claim 8, wherein both such at least one radio frequency signal of said at least one plasma creator and such at least one radio frequency signal of said at least one enveloper transmit from a common electrode of said at least two electrodes.

10) A system, relating to altering control of a plasma between activating a surface of at least one substrate with minimal etching and etching the surface of the at least one substrate, comprising:
a) at least one container structured and arranged to contain the at least one substrate and the plasma;
b) at least two electrodes structured and arranged to interact with at least one electromagnetic signal; and
c) at least one plasma creator structured and arranged to create the plasma;
d) wherein the plasma comprises at least one surface-etching constituent and at least one activating constituent; and
e) at least one positioner structured and arranged to position the surface within the plasma;
f) wherein said at least one positioner comprises one of said at least two electrodes; and
g) wherein said at least one positioner comprises at least one adjuster structured and arranged to adjust distance between said at least two electrodes; and
h) at least one envelope generator structured and arranged to generate at least one envelope inside said at least one container;
i) wherein said at least one adjuster comprises at least one etching-distance setting and at least one activation-distance setting;
j) wherein said at least one envelope generator comprises at least one etching-envelope setting and at least one activation-envelope setting;
k) wherein, when said at least one adjuster is set to said at least one activation-distance setting and when said at least one envelope generator is set to said at least one activation-envelope setting,
i) said at least one envelope generator is structured and arranged to generate such at least one envelope structured and arranged to control plasma composition to minimize content of such at least one surface-etching constituent of the plasma and maximize content of such at least one activating constituent of the plasma adjacent the surface, and
ii) the plasma is controlled to activate the surface of the at least one substrate with minimal etching; and
l) wherein, when said at least one adjuster is set to said at least one etching-distance setting and when said at least one envelope generator is set to said at least one etching-envelope setting,
i) said at least one envelope generator is structured and arranged to generate such at least one envelope structured and arranged to permit such at least one surface-etching constituent of the plasma adjacent the surface, and
ii) the plasma is allowed to etch the surface of the at least one substrate.

11) The system, according to claim 10, wherein at least one of said at least two electrodes is at ground potential.

12) The system, according to claim 11, wherein at least one of said at least two electrodes is structured and arranged to transmit at least one radio frequency signal.

13) The system, according to claim 12, wherein said at least one plasma creator and said at least one envelope generator each comprise such at least one radio frequency signal.

14) The system, according to claim 13, wherein both such at least one radio frequency signal of said at least one plasma creator and such at least one radio frequency signal of said at least one envelope generator transmit from a common electrode of said at least two electrodes.

15) The system, according to claim 14, wherein said at least one etching-envelope setting comprises at least one integral multiple frequency, wherein frequency of such at least one radio frequency signal of said at least one plasma creator is an integral multiple of frequency of such at least one radio frequency signal of said at least one envelope generator.

16) The system, according to claim 14, wherein said at least one activation-envelope setting comprises at least one non-integral multiple frequency, wherein frequency of such at least one radio frequency signal of said at least one plasma creator is a non-integral multiple of frequency of such at least one radio frequency signal of said at least one envelope generator.

17) A system, relating to controlling a plasma to activate a surface of at least one substrate with minimal etching, comprising:
a) container means for containing the at least one substrate and the plasma; and
b) plasma creator means for creating the plasma;
c) wherein the plasma comprises at least one surface-etching constituent and at least one activating constituent; and
d) positioner means for positioning the surface within the plasma; and
e) enveloper means for enveloping the at least one substrate and at least partially the plasma in at least one envelope;
f) wherein said enveloper means comprises controller means for controlling plasma composition to minimize content of such at least one surface-etching constituent of the plasma and maximize content of such at least one activating constituent of the plasma adjacent the surface; and
g) wherein the plasma is controlled to activate the surface of the at least one substrate with minimal etching.

18) The system, according to claim 17, wherein enveloper means comprises geometry controller means for controlling geometry of such at least one envelope.

19) The system, according to claim 17, wherein said enveloper means comprises said controller means for controlling plasma composition to minimize content of charged particles and maximize content of uncharged radicals adjacent the surface.

20) The system, according to claim 17, wherein said positioner means comprises adjuster means for adjusting position of the surface.
